(19) United States
(12) Patent Application Publication
(10) Pub. No.: US 2012/0044641 A1
(43) Pub. Date: Feb. 23, 2012

(54) ELECTRONIC DEVICE

(75) Inventors: XIAO-SU ZHU, Shenzhen City (CN); YANG LI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/028,777

(22) Filed: Feb. 16, 2011

(30) Foreign Application Priority Data
Aug. 19, 2010 (CN) 201010264751.6

(51) Int. Cl. H05K 7/20

(52) U.S. Cl. 361/692; 361/700

(57) ABSTRACT

An electronic device includes an enclosure. The enclosure includes a main body and a cover attached to the main body. A first air intake and a second air outlet are defined in the cover. A first heat device and a circuit board are attached to the main body. The first heat device includes a plurality of first fins. A second heat device is located on the circuit board and configured to dissipate heat from a CPU located on the circuit board. A heat pipe is located between the first heat device and the second heat device. A distance between adjacent first fins is in a range of 5.3-5.7 mm, and the second heat device, the first heat device and the first air outlet cooperatively define an airflow passage configured for directing air to flow through to the electronic device.

### BACKGROUND

1. Technical Field

The present disclosure relates to device cooling, more particularly to an electronic device dissipating heat from a central processing unit.

2. Description of Related Art

Heat dissipating devices often include one or more fans and heat sinks corresponding thereto. For example, a central processing unit (CPU) in an all-in-one (AIO) computer can experience deteriorated operational stability and damage associated electronic components if heat is not dissipated efficiently.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an electronic device in accordance with an embodiment as disclosed.

FIG. 2 is similar to FIG. 1, but shows a first and second heat devices fixed to a circuit board.

FIG. 3 is an assembled view of FIG. 1.

FIG. 4 is a diagram showing a software-generated relationship between temperature and distances between two adjacent first fins.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

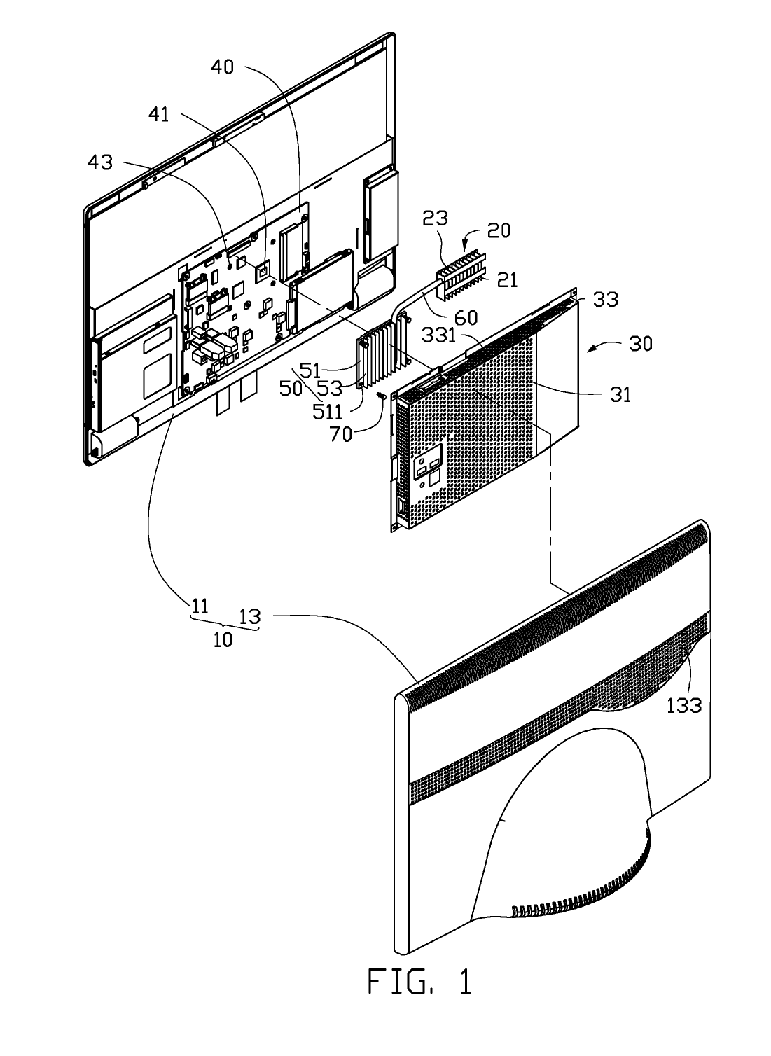

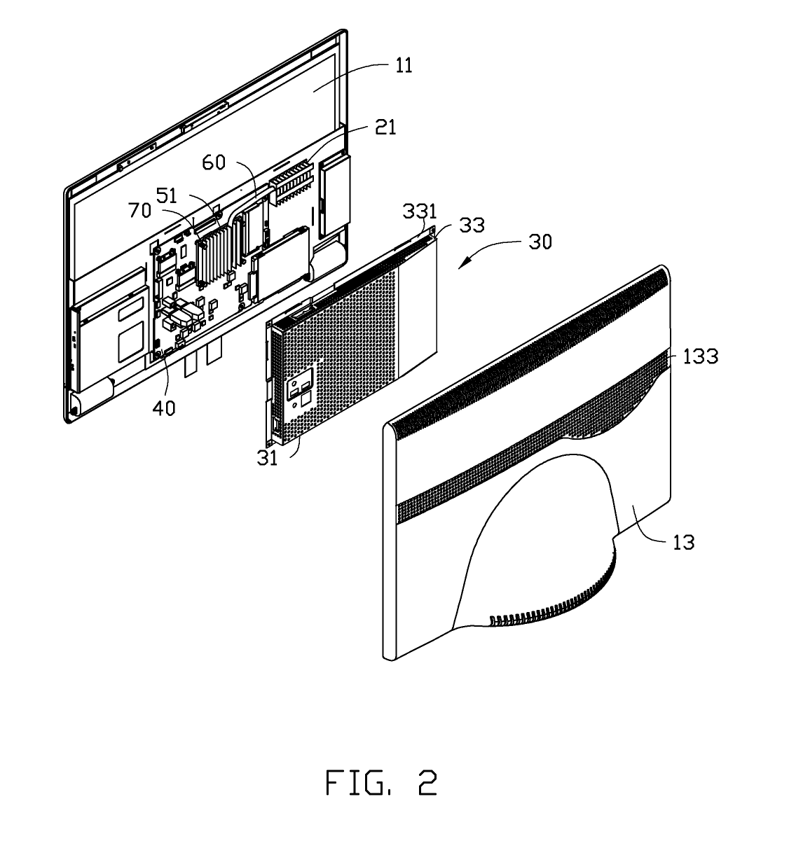

Referring to FIGS. 1 and 2, an electronic device in accordance with an embodiment includes an enclosure 10 and a casing 30 received in the enclosure 10. In one embodiment, the electronic device is an AIO.

The enclosure 10 includes a main body 11 and a cover 13 attached to the main body 11. A first heat device 20 and a circuit board 40 are attached to the main body 11. The first heat device 20 is located on one side of the circuit board 40, and includes a plurality of first fins 21 and a first base 23 configured for securing the plurality of first fins 21. The plurality of first fins 21 cooperatively defines a plurality of first air path for air passing through. A distance of every two adjacent first fins 21 equals or exceeds 5.3 mm, but less than or equal to 5.7 mm. In one embodiment, the distance of two adjacent first fins 21 is 5.5 mm. A CPU 41 is disposed on the circuit board 40, and four securing holes 43 are defined in the circuit board 40, surrounding CPU 41.

A second heat device 50 is attached to the CPU 41, and includes a second base 51 and a plurality of second fins 53. The plurality of second fins 53 cooperatively define a plurality of second air path for air passing through. Four mounting holes 511 are respectively defined in four corners of the base, corresponding to the four securing holes 43.

A heat pipe 60 is located between the first heat device 20 and the second heat device 50. In one embodiment, the heat pipe 60 is L-shaped, a first end of the heat pipe 60 is substantially perpendicularly secured to the plurality of first fins 21, and a second end of the heat pipe 60 is located between two adjacent second fins 53.

A plurality of first air intakes (not shown) is defined in the bottom of the cover 13, and a plurality of first air outlets 133 is defined in the center of the cover 13.

A plurality of through holes 31 is defined in the casing 30. The casing 30 includes first flanges (not shown) and an opposite second flange 33. A plurality of second air intakes (not shown) is defined in the first flange, and a plurality of second air outlets 331 is defined in the second flange 33.

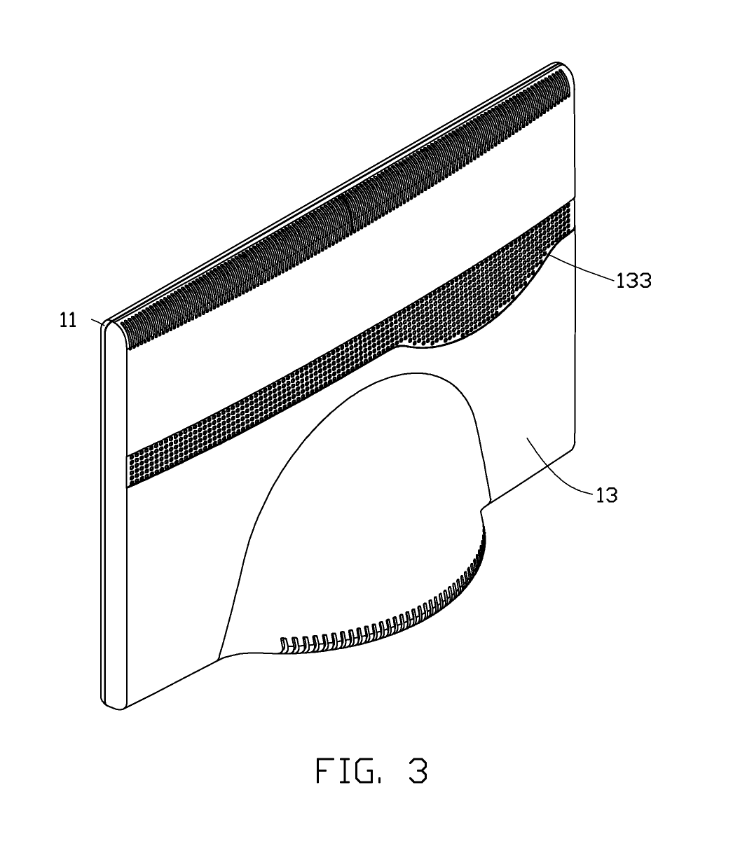

Referring to FIGS. 2 and 3, in assembly, the first heat device 20 is placed on one side of the circuit board 40, and the second heat device 50 is placed on the CPU 41. The four securing holes 43 of the main body 11 are aligned with the four mounting holes 511 of the second heat device 50. Four fixing members 70 are received in the four securing holes 43 and the four mounting holes 511. Thus, the second heat device 50 is mounted to the main body 11. In one embodiment, the first heat device 20 is mounted to the main body 11 by fasteners or clasps. The casing 30 is attached to the main body 11, and the circuit board 40, the first heat device 20 and the second heat device 50 are accommodated in the casing 30.

In use, the second heat device 50 absorbs heat from the CPU, and some heat is transmitted to the first heat device 20 by the heat pipe 60. The air flows into the enclosure 10 from the first air intakes of the enclosure 10, and passes through the through holes 31 and the second intakes of the casing 30. Then, the air flows to the CPU 41, the first heat device 20 and the second heat device 50, and out of the second air outlets 331 of the casing 30, the first air outlets 133 of the enclosure 10. Accordingly, heat is dissipated from the first heat device 20 and the second heat device 50.

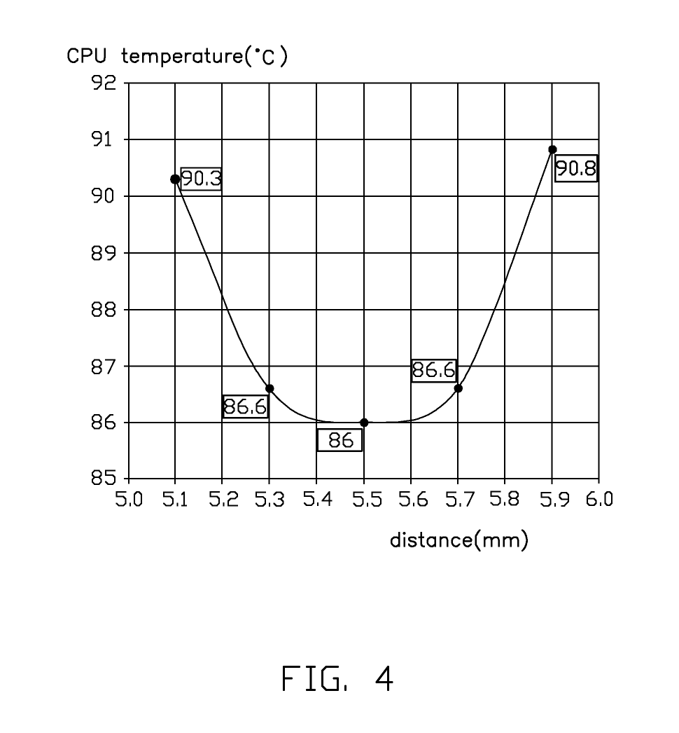

Referring to FIG. 4, a simulation application of an embodiment such as Icepak generates a working temperature of the CPU 41 under conditions in which a normal temperature is 35° C. and the distance between adjacent first fins 21 is in a range of 5.0-6.0 mm. The lowest temperature of the CPU 41 is 86° C. when the distance between the two adjacent first fins 21 is 5.5 mm. When the distance between the two adjacent first fins 21 is from 5.1 to 5.5 mm, the temperature of the CPU 41 drops to 86° C. from 90.3° C. When the distance between the two adjacent first fins 21 is from 5.5 to 5.9 mm, the temperature of the CPU 41 increases to 90.8° C. from 86° C. In one embodiment, when the temperature of the CPU 41 is in a range 86-86.6° C., the CPU 41 operates stably. Referring to FIG. 4, when the distance between the two adjacent first fins 21 is 5.3 mm or 5.7 mm, the temperature of the CPU 41 for both is 86.6° C. When the distance between the two adjacent first fins 21 is increased to 5.5 mm from 5.3 mm, the temperature of the CPU 41 is decreased to 86° C. from 86.6° C. When the distance between the two adjacent first fins 21 is increased to 5.7 mm from 5.5 mm, the temperature of the CPU 41 is increased to 86.6° C. from 86° C. Therefore, when the distance between the two adjacent first fins 21 is in the 5.3-5.7 mm range, the temperature of the CPU 41 is in a range 86-86.6° C., and the CPU 41 can operate stably. When the distance between the two adjacent first fins 21 is 5.5 mm, the temperature of the CPU 41 is 86° C. Thus, the 5.5 mm is shown to be an optimum distance between the two adjacent first fins 21.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. An electronic device comprising:
an enclosure comprising a main body and a cover attached to the main body, a first air intake and a first air outlet defined in the cover;
a first heat device attached to the main body, the first heat device comprising a plurality of first fins, and
a circuit board attached to the main body, a second heat device located on the circuit board and configured to dissipate a heat from a CPU located on the circuit board, a heat pipe located between the first heat device and the second heat device ;
wherein a distance between adjacent first fins is in a range of 5.3-5.7 mm, the first air intake, the second heat device, the first heat device and the first air outlet cooperatively define an airflow passage configured for directing air to flow through to the electronic device.

2. The electronic device of claim 1, wherein the distance between adjacent first fins is 5.5 mm.

3. The electronic device of claim 1, further comprising a casing, and the circuit board and the first heat device are received in the casing.

4. The electronic device of claim 3, wherein a second air intake and a second air outlet are defined in the casing, the second air intake corresponds to the first air intake, and the second air outlet corresponds to the first air outlet.

5. The electronic device of claim 1, wherein a first end of the heat pipe is substantially perpendicularly attached to the plurality of first fins, the second heat device comprises a plurality of second fins, a second end of the heat pipe is located between two adjacent second fins.

6. The electronic device of claim 5, wherein the second heat device comprises a base securing the plurality of second fins, and the base is attached to the circuit board.

7. The electronic device of claim 1, wherein the heat pipe is L-shaped.

8. An electronic device comprising:
an enclosure comprising a main body and a cover attached to the main body;
a first heat device attached to the main body, the first heat device comprising a first base and a plurality of first fins, and
a circuit board attached to the main body, a second heat device located on the circuit board and configured to dissipate a heat from a CPU located on the circuit board, a heat pipe located between the first heat device and the second heat device;
wherein the first heat device is separated from the circuit board, the second heat device comprises a plurality of second fins, a first end of the heat pipe is substantially perpendicular to and attached to the plurality of first fins, and a second end of the heat pipe is located between two adjacent second fins.

9. The electronic device of claim 8, wherein a distance between adjacent first fins is in a range of 5.3-5.7 mm.

10. The electronic device of claim 9, wherein the distance between two adjacent first fins is 5.5 mm.

11. The electronic device of claim 8, further comprising a casing, and the circuit board and the first heat device are received in the casing.

12. The electronic device of claim 11, wherein a first air intake and a first air outlet are defined in the cover, a second air intake and a second air outlet are defined in the casing, the second air intake corresponds to the first air intake, and the second air outlet corresponds to the first air outlet.

13. The electronic device of claim 8, wherein the second heat device comprises a second base attached to the plurality of second fins, and the second base is attached to the circuit board.

14. The electronic device of claim 8, wherein the heat pipe is L-shaped.
